(19) United States
(12) Patent Application Publication
(10) Pub. No.: US 2021/0090955 A1
(43) Pub. Date: Mar. 25, 2021

(54) Method for preparing a heterostructure

(71) Applicant: SHANGHAI INSTITUTE OF MICROSYSTEM AND INFORMATION TECHNOLOGY, CHINESE ACADEMY OF SCIENCES, Shanghai (CN)

(72) Inventors: Xin OU, Shanghai (CN); Shumin WANG, Shanghai (CN); Chang WANG, Shanghai (CN); Tiangui YOU, Shanghai (CN); Yanchao ZHANG, Shanghai (CN); Kai HUANG, Shanghai (CN); Lijuan WANG, Shanghai (CN); Jiajie LIN, Shanghai (CN); Wenwu PAN, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 16/640,059

(22) PCT Filed: Dec. 7, 2017
(86) PCT No.: PCT/CN2017/114971

§ 371 Date: Dec. 2, 2020

(30) Foreign Application Priority Data
Aug. 24, 2017 (CN) 201710735726.3

(51) Int. Cl. H01L 21/78; H01L 21/02; C30B 23/02; C30B 25/18; C30B 29/40; C30B 33/00

(52) U.S. Cl. CPC H01L 21/7813; C30B 33/005; H01L 21/02392; H01L 21/02395; H01L 21/02398; H01L 21/024; H01L 21/0237; H01L 21/02461; H01L 21/02463; H01L 21/02466; H01L 21/0245; H01L 21/02502; H01L 21/02549; C30B 23/025; C30B 25/183; C30B 29/40; H01L 21/02381

(57) ABSTRACT

The present disclosure provides a method for preparing heterostructure, which includes providing a donor substrate and forming a sacrificial layer on a surface of the donor substrate; forming a thin film cover layer on a surface of the sacrificial layer, wherein a top surface of the thin film cover layer is an implantation surface; performing ion implantation from the implantation surface, such that a defect layer is formed in the sacrificial layer; providing an acceptor substrate, and bonding the acceptor substrate to the implantation surface of the thin film cover layer; removing the sacrificial layer along the defect layer. The method for preparing the heterostructure of the present disclosure can successfully transfer the thin film cover layer to the acceptor substrate. The present disclosure can provide a compliant substrate, while the semiconductor donor substrate material can be reused, therefore is energy-efficient and environmental-friendly.

### CROSS REFERENCES TO RELATED APPLICATIONS

This is a Sect. 371 National Stage application of a PCT International Application No. PCT/CN2017/114971, filed on Dec. 7, 2017, which claims priority of a Chinese Patent Applications No. 2017107357263, filed on Aug. 24, 2017, the content of which is hereby incorporated by reference in its entirety for all purposes.

### TECHNICAL FIELD

The disclosure relates to the technical field of silicon-based photoelectric integration application, and in particular, to a method for preparing heterostructure.

### BACKGROUND

In recent years, silicon-based compound semiconductor integration technologies have been focused. The traditional process uses silicon material as a light emitter. Silicon is an indirect bandgap semiconductor with poor light-emitting performance. Although some researchers have processed silicon materials into nanometer or quantum size to develop their non-linear optical properties, the performances of silicon material are still not as good as the compound semiconductors. Compound semiconductors, due to their high electron mobility as well as high-efficiency light emission advantages derived from direct band gaps, have always been a hot topic in the scientific research and industries. However, compound semiconductors are expensive, and are difficult to be used in large-size integration, therefore, it is difficult for compound semiconductors to be industrialized. Therefore, heterogeneous integration technology that combines compound semiconductors and silicon integrated circuits have become a research hot topic in the field of photoelectric integration field. Heterogeneous integration technology provides more freedom for the design and preparation of devices and systems, improves device performance, and reduces manufacturing cost, thereby having broad application prospects in the fields of electronics, optoelectronics, spintronics, biosensing, and photovoltaic solar energy.

In addition, compliant substrates have also been a hot topic of research. The epitaxial layer nucleates and grows on the substrate surface. Threading dislocations are easily formed when the islands are combined, and the dislocations would run through the entire epitaxial layer. If a compliant substrate material is used, the atomic force between the epitaxial island atomic cluster and the very thin compliant substrate is smaller than that of the homogeneous material. Part of the threading dislocations may be released by sliding at the interface between the compliant substrate and the epitaxial layer, and the ultra-thin compliant substrates have a much lower atomic binding force to the epitaxial layer than that to the bulk silicon substrate. Therefore, the application of compliant substrates in devices is also very promising.

At present, there are two solutions for heterogeneous integration processes: epitaxial growth and ion-slicing technology. For traditional epitaxial methods, the heteroepitaxial layer on the silicon substrate has a high dislocation density, coupled with the anti-phase domain and self-doping effects, the carrier mobility would be affected, and the leakage current of the device would be increased. Ion-slicing technology is a commonly used method for heterogeneous integration, which combines the cutting technology of ion implantation defect engineering and the layer transfer technology based on wafer bonding. The thin layer is cut on a single crystal substrate and transferred to a cheap foreign substrate, thereby having certain economic benefits. For ion-slicing technology, first, ion implantation (hydrogen or helium ions) produces a Gaussian distribution. At a specific position parallel to the surface (where the implanted ion density is the highest or the lattice damage is the greatest), a defect layer is formed. The wafer ion-implanted would crack along the defect layer in the subsequent annealing process. However, the surface roughness caused by the layer cracking process and the surface defects introduced by the ion implantation bring great trouble to the subsequent work. Etching also would increase steps and even introduce impurity particles.

Therefore, it is necessary to provide a method for preparing heterostructure, so as to solve the above problems.

### SUMMARY

The present disclosure provides a method for preparing heterostructure, which solves the problems of large leakage current, easy to introduce surface defects and impurity particles caused by methods for forming heterostructure in the traditional technology.

The present disclosure provides a method for preparing heterostructure, including: 1) providing a donor substrate and forming a sacrificial layer on the surface of the donor substrate; 2) forming a thin film cover layer on the surface of the sacrificial layer, and the top surface of the thin film cover layer is the implantation surface; 3) performing ion implantation into the implantation surface, so that a defect layer is formed in the sacrificial layer; 4) providing an acceptor substrate and bonding the acceptor substrate to the implantation surface of the thin film cover layer; 5) removing the sacrificial layer along the defect layer, so as to separate the acceptor substrate bonded with the thin film cover layer from the donor substrate, to obtain heterostructure of acceptor substrate-thin film cover layer.

As a preferred solution of the present disclosure, step 1) further includes forming a buffer layer on the surface of the donor substrate, and the buffer layer is formed between the donor substrate and the sacrificial layer.

As a preferred solution of the present disclosure, in step 1), the material of the sacrificial layer is an aluminum-containing compound.

As a preferred solution of the present disclosure, the aluminum-containing compound is any one of a group consisting of AlP, AlAs, AlSb, and Al (GaIn) (PAsSb).

As a preferred solution of the present disclosure, the method further includes step 6), surface-treating the sacrificial layer obtained after stripping by autoxidation, such that the sacrificial layer is easy to clean.

As a preferred solution of the present disclosure, in step 2), the thickness of the thin film cover layer is 20 to 1000 nm.

As a preferred solution of the present disclosure, in step 1), the donor substrate is any one of a group consisting of a Si substrate, a Ge substrate, a GaP substrate, a GaAs substrate, an InP substrate, a GaSb substrate, an InAs substrate, an InSb substrate, a group II-VI substrate, and a group IV-VI substrate.

As a preferred solution of the present disclosure, in step 3), the defect layer is spaced from the top surface of the sacrificial layer, and is spaced from the bottom surface of the sacrificial layer.

As a preferred solution of the present disclosure, in step 3), the ion implantation is any one of a group consisting of hydrogen ion implantation, helium ion implantation, and hydrogen-helium ion co-implantation.

As a preferred solution of the present disclosure, the energy of the ion implantation is 10 to 200 keV, the dose of the ion implantation is 1×10¹⁶ to 3×10¹⁷ cm⁻², and the temperature at which the ion implantation is performed is −50 to 300° C.

As a preferred solution of the present disclosure, in step 4), the bonding temperature is from room temperature to 500° C.

As a preferred solution of the present disclosure, in step 4), the acceptor substrate is any one of a group consisting of a silicon substrate, a silicon on insulator substrate, and a silicon carbide substrate.

As a preferred solution of the present disclosure, in step 5), the structure obtained in step 4) is annealed to remove the sacrificial layer along the defect layer, and the annealing temperature is 50 to 500° C.

As described above, the method for preparing the heterostructure of the present disclosure has the following beneficial effects:

1) In the present disclosure, materials that are susceptible to chemical corrosion such as aluminides are used as sacrificial layers. After layer cracking, by using the characteristics that aluminides are easy to be oxidized (in a general indoor environment) or by performing some simple etching, simplifying the processing of treating the sacrificial layer and making the surface of the obtained silicon substrate and semiconductor substrate clean;

2) The method for preparing the heterostructure of the present disclosure can successfully transfer the thin film cover layer to the acceptor substrate. The present disclosure can provide a compliant substrate, while the semiconductor donor substrate material can be reused, therefore is energy-efficient and environmental-friendly.

### BRIEF DESCRIPTION OF THE DRAWINGS

FIG. 1 shows a flow chart of a method for preparing heterostructure according to the present disclosure.

FIG. 2-FIG. 9 (b) are schematic diagrams corresponding to each step of the preparation of the silicon-based heterostructure according to the present disclosure.

### DESCRIPTION OF REFERENCE NUMERALS

11 Donor substrate
12 Sacrificial layer
121 First sacrificial layer
122 Second sacrificial layer
13 Buffer layer
14 Thin film cover layer
141 Implantation surface
15 Defect layer
16 Acceptor substrate
S1˜S5 Step 1 to Step 5

### DETAILED DESCRIPTION OF THE PREFERRED EMBODIMENTS

The embodiments of the present disclosure will be described below through exemplary embodiments. Those skilled in the art can easily understand other advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

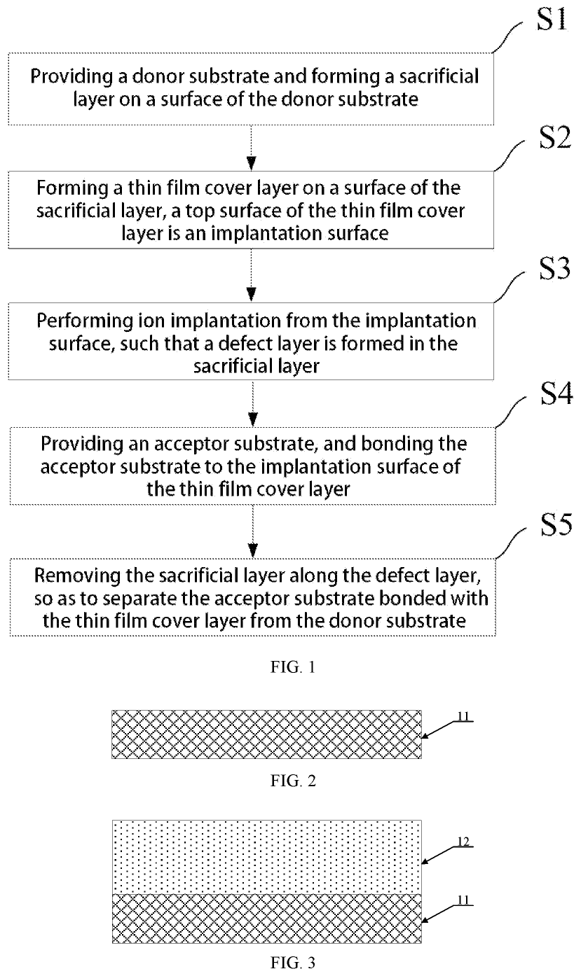

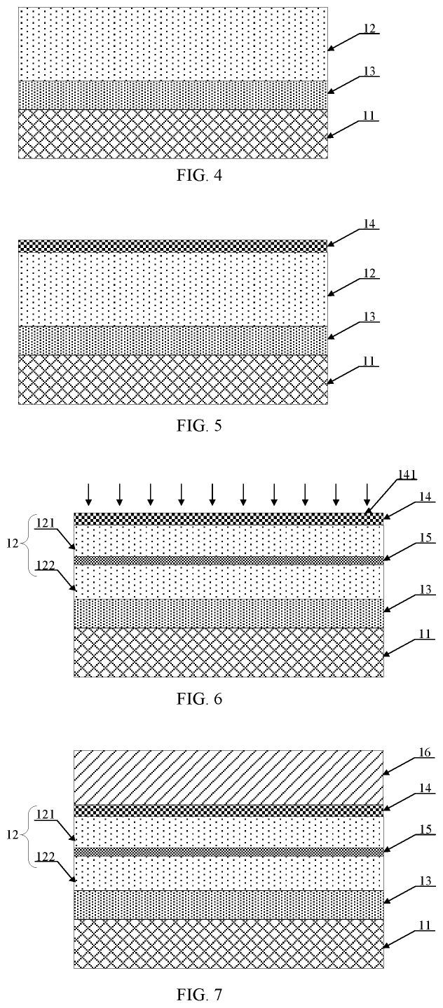

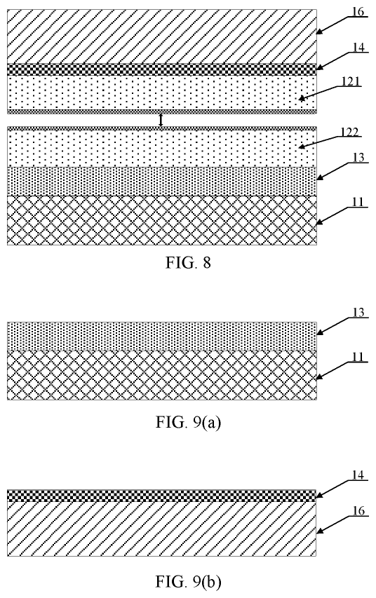

Referring to FIGS. 1 to 9(b). It needs to be stated that the drawings provided in the following embodiments are just used for schematically describing the basic concept of the present disclosure, thus only illustrating components only related to the present disclosure and are not drawn according to the numbers, shapes and sizes of components during actual implementation, the configuration, number and scale of each component during actual implementation thereof may be freely changed, and the component layout configuration thereof may be more complex.

As shown in FIGS. 1 to 9(b), the present disclosure provides a method for preparing heterostructure, including: 1) providing a donor substrate and forming a sacrificial layer on the surface of the donor substrate; 2) forming a thin film cover layer on the surface of the sacrificial layer, and a top surface of the thin film cover layer is an implantation surface; 3) performing ion implantation from the implantation surface, such that a defect layer is formed in the sacrificial layer; 4) providing an acceptor substrate, and bonding the acceptor substrate to the implantation surface of the thin film cover layer; 5) The sacrificial layer is removed along the defect layer, so as to separate the acceptor substrate bonded with the thin film cover layer from the donor substrate, to obtain heterostructure of acceptor substrate-thin film cover layer.

The method for preparing the heterostructure according to the present disclosure will be described in detail below with reference to the drawings.

As shown in S1 in FIG. 1 and FIGS. 2 to 4, step 1), providing a donor substrate 11 and forming a sacrificial layer 12 on the surface of the donor substrate 11;

As an example, in step 1), the donor substrate 11 is any one of a group consisting of a Si substrate, a Ge substrate, a GaP substrate, a GaAs substrate, an InP substrate, a GaSb substrate, an InAs substrate, an InSb substrate, a group I-V substrate, and a group IV-VI substrate.

Specifically, the donor substrate 11 is used as a supporting substrate for the preparation process. The group IV-VI substrate refers to a compound composed of group IV-VI elements. Other similar names are deduced by analogy, and are not repeated here. In this embodiment, the donor substrate 11 is preferably a GaSb substrate.

As an example, in step 1), the material of the sacrificial layer 12 is an aluminum-containing compound.

As an example, the aluminum-containing compound is any one of a group consisting of AlP, AlAs, AlSb, and Al (GaIn) (PAsSb).

Specifically, on the one hand, the sacrificial layer 12 is grown by an epitaxial method, so that the sacrificial layer has a smooth interface with adjacent layers. On the other hand, the present disclosure may use a selective etching method to etch the sacrificial layer, so as to further ensure that the original smooth surface is not damaged, without the need to planarize the defective surface as in the existing technology. In addition, the material of the sacrificial layer 12 is, AlSb, an aluminum-containing compound or other materials that are susceptible to chemical corrosion. The purpose is to utilize the characteristics of their tendency to be corroded. For example, aluminides are easily oxidized in the air. Therefore, the sacrificial layer 12 can be easily removed after stripping, so that the separated structure has a clean and high-quality surface. A silicon-based heteroepitaxial structure with a clean surface and a semiconductor donor substrate structure with a clean surface are obtained. In addition, the thickness of the sacrificial layer 12 ranges from 200 to 1200 nm, preferably 400 to 800 nm, more preferably 500 to 700 nm. In this embodiment, the sacrificial layer 12 is an AlSb sacrificial layer and the thickness is 600 nm.

As an example, step 1) further includes forming a buffer layer 13 on the surface of the donor substrate 11. The buffer layer 13 is formed between the donor substrate 11 and the sacrificial layer 12.

Specifically, the buffer layer 13 is formed to facilitate interface matching between the donor substrate and the sacrificial layer. The material of the buffer layer 13 may be, but is not limited to, germanium, or a group II-v material grown at a low temperature. In this embodiment, a GaSb buffer layer is selected. The growth method of the buffer layer 13 may be, but is not limited to, molecular beam epitaxy or an organic metal vapor phase growth method. The thickness of the buffer layer 13 may be, but not limited to, 200 to 1000 nm, preferably 400-800 nm, more preferably 500-700 nm. In this embodiment, 550 nm is selected.

As shown in S2 in FIG. 1 and FIG. 5, step 2), forming a thin film cover layer 14 on the surface of the sacrificial layer 12. The top surface of the thin film cover layer 14 is an implantation surface.

As an example, in step 2), the thin film cover layer 14 is a GaSb layer.

As an example, in step 2), the thickness of the thin film cover layer 14 ranges from 20 to 1000 nm.

Specifically, on the surface of the sacrificial layer 12, a structure of the heterostructure is formed. In the present disclosure, the structure is a thin film cover layer 14, which may be used as a compliant substrate layer according to the actual need, and there are no specific restrictions here. In this embodiment, the thickness of the thin film cover layer 14 is 160 to 800 nm, preferably 180 to 300 nm, or 30 to 150 nm, preferably 50 to 80 nm. In this embodiment, 200 nm is selected and the thin film cover layer 14 is a GaSb layer.

As shown in S3 in FIG. 1 and FIG. 6, step 3), performing ion implantation into the implantation surface 141, such that a defect layer 15 is formed at a preset depth of the sacrificial layer 12.

As an example, in step 3), there is a spacing between the defect layer 15 and the top surface of the sacrificial layer 12 and spacing between the defect layer 15 and the bottom surface of the sacrificial layer 12. That is, the depth of the defect layer 15 is greater than the thickness of the thin film cover layer 14, and less than the sum of the thicknesses of the thin film cover layer 14 and the sacrificial layer 12.

Specifically, a preset depth is defined in the sacrificial layer 12. When the ions are implanted from the implantation surface, the energy of the implanted ion is sufficient for the implanted ion to reach the preset depth and form the defect layer 15 at the preset depth. The defect layer is used for separating in a subsequent process to obtain the desired heterostructure. The defect layer divides the sacrificial layer into a first sacrificial layer 121 and a second sacrificial layer 122.

As an example, in step 3), the ion implantation is any one of a group consisting of hydrogen ion implantation, helium ion implantation, and hydrogen-helium ion co-implantation.

As an example, the energy of the ion implantation ranges from 10 to 200 keV, the dose of the ion implantation ranges from 1×10¹⁶ to 3×10¹⁷ cm⁻², and the temperature of the ion implantation ranges from −50 to 300° C.

Specifically, the ion species of the ion implantation may also be other species of ions capable of achieving the same or similar functions, which is not limited herein. In addition, when the ion implantation is hydrogen-helium ion co-implantation, He ions are firstly implanted, and then H ions; or, H ions are firstly implanted, and then He ions; or, H ions and He ions are implanted simultaneously.

Preferably, the implantation depth of the He ions is the same as or similar to the implantation depth of the H ions. Specifically, in the ion implantation process, the energy of the implanted ions may be adjusted so that the implantation depths of the two ions are the same. That is, the energy of the implanted ions determines the depth of the ion implantation (i.e., the depth of the defect layer 15 described in this embodiment). The higher the energy of the implanted ion is, the greater the depth of the defect layer 15 is. Whereas, the lower the energy of the implanted ion is, the less of the depth of the defect layer 15 is. Further, the implantation depth of the He ions is the same as the implantation depth of the H ions, which can ensure that the range (Rp) of He ions is near the range of the H ion implantation, promoting the subsequent stripping. Of course, under the premise of realizing this function, the implantation depth of the He ions and the implantation depth of the H ions may also be close.

Specifically, during the ion implantation, the temperature of the ion implantation is maintained at −50 to 300° C. At this time, the concentration of the implanted ion shows a Gaussian distribution in the sacrificial layer 12. A crystal defect is introduced into the sacrificial layer to form a defect layer 15. Preferably, the temperature is −30° C. to −10° C., or 10° C. to 40° C., or 100° C. to 200° C. In this embodiment, the temperature is maintained at room temperature, thereby reducing the additional energy consumption required by controlling the implantation temperature, and decreasing the bubbling phenomenon on the surface of the sample during the high-temperature implantation process, which is beneficial to the subsequent bonding process.

Specifically, the implantation energy is preferably 50 to 150 keV. In this embodiment, the implantation energy is 75 KeV. The implantation dose is preferably 2×10¹⁶ to 1×10¹⁷ cm⁻². In this embodiment, the implantation dose is 5×10¹⁶ cm⁻². The implanted ion can reach an implantation depth of 660 nm.

As shown in S4 in FIG. 1 and FIG. 7, step 4), providing an acceptor substrate 16, and bonding the acceptor substrate 16 to the implantation surface 141 of the thin film cover layer 14;

As an example, in step 4), the bonding temperature ranges from room temperature to 500° C.

As an example, in step 4), the acceptor substrate 16 is any one of a group consisting of a silicon substrate, a silicon on insulator substrate, and a silicon carbide substrate.

Specifically, the acceptor substrate 16 is the other part of the heterostructure. In addition, the acceptor substrate 16 is any one of a group consisting of silicon, silicon dioxide, sapphire, silicon carbide, diamond, gallium nitride, gallium arsenide, or glass. In this embodiment, the acceptor substrate 16 is preferably a silicon-based substrate.

Specifically, the bonding method is any one of a group consisting of direct bonding, growing medium layer (such as SiO₂, etc.) bonding, polymer bonding, and spinning-on-glass bonding. In other embodiments, the bonding may be realized by other bonding methods that achieve the same function and the same effect, it is not limited herein. Through the above bonding method, defects may be controlled within a very small thickness range near the interface, such that the internal lattice in the film is not affected, and the implantation surface 141 and one surface of the acceptor substrate 16 are firmly bonded. The bonding temperature ranges from 30 to 200° C., preferably 50 to 80° C., or 260 to 350° C. In this embodiment, the bonding temperature is 35° C.

As shown in S5 in FIG. 1 and FIG. 8s to 9(b), step 5), removing the sacrificial layer 12 along the defect layer 15, so as to separate the acceptor substrate 16 bonded with the thin film cover layer 14 from the donor substrate 11, so as to obtain heterostructure of acceptor substrate-thin film cover layer, thereby obtaining a compliant substrates layer composed of the thin film cover layer.

As an example, in step 5), the structure obtained in step 4) is annealed, so as to remove the sacrificial layer 12 along the defect layer 15.

As an example, the annealing temperature is 50 to 500° C.

Specifically, the defect layer 15 may be cracked by annealing, such that the sacrificial layer 12 is cracked. The annealing temperature is preferably 100 to 400° C. In this embodiment, the annealing temperature is 250° C.

In addition, two-stage annealing may be used. Specifically, first, annealing at a low temperature (such as 10 to 30° C.) for a long time, such that the H ions and He ions have sufficient migration energy to form defects. That is, H or He ion is diffused in the material, and bonded with defects in the material. The low temperature also ensures that a larger number of H ions and He irons do not escape from the InP substrate. Then, annealing at a higher temperature (such as 260 to 300° C.), such that the defects in the defect layer 15 are connected into a defect band, resulting in the stripping. During the annealing process, the aggregation of H and/or He is thermally expanded, thereby increasing the pressure within the defects, causing the breaking of the chemical bonds and the increment of the defects, forming a plateau-type defect (defect band) at the defect layer, and eventually causing the stripping of the sacrificial layer. Therefore, compared with the direct annealing process, the composite annealing process combining low temperature pre-annealing and high temperature post-annealing shortens the annealing time.

As an example, step 6) is further included, the sacrificial layer obtained after the stripping is surface-treated so that the sacrificial layer is easy to clean.

As an example, a process for performing the surface treatment includes natural oxidation or chemical etching.

Specifically, after the two parts of the structure are separated, a surface treatment step is included. The surface treatment includes autoxidation or selective etching. In this embodiment, after layer cracking due to annealing, the structure is placed in the air for oxidizing of the sacrificial layer. Since the sacrificial layer is easy to oxidize, it will be oxidized in the air. After the sacrificial layer is oxidized, the layer cracking surface is treated with an air pump to obtain two clean surfaces, which are the clean thin film cover layer surface (an opposite layer of the implantation surface) and a clean buffer layer surface. As a result, high-quality heterostructure is obtained. The present disclosure provides a high-quality compliant substrate, while obtaining a high-quality donor substrate and a buffer layer on the surface of the donor substrate. The donor substrate or the donor substrate with the buffer layer may be reused in the preparation of other heterostructures.

In summary, the present disclosure provides a method for preparing heterostructure, which includes providing a donor substrate and forming a sacrificial layer on the surface of the donor substrate; forming a thin film cover layer on the surface of the sacrificial layer, and a top surface of the thin film cover layer is an implantation surface; performing ion implantation from the implantation surface, such that a defect layer is formed in the sacrificial layer; providing an acceptor substrate and bonding the acceptor substrate to the implantation surface of the thin film cover layer; removing the sacrificial layer along the defect layer, so as to separate the acceptor substrate bonded with t the thin film cover layer from the donor substrate, to obtain heterostructure of acceptor substrate-thin film cover layer. Through the above solution, the present disclosure introduces materials that are susceptible to chemical corrosion such as aluminides as sacrificial layers. After layer cracking, by using the characteristics that aluminides are easy to be oxidized (in a general indoor environment) or by performing some simple etching, simplifying the processing of treating the sacrificial layer and making the surfaces of the obtained silicon substrate material and semiconductor substrate material clean. The method for preparing the heterostructure of the present disclosure can successfully transfer the thin film cover layer to the acceptor substrate. The present disclosure can provide a compliant substrate, while the semiconductor donor substrate material can be reused, therefore is energy-efficient and environmental-friendly. Therefore, the present disclosure effectively overcomes various shortcomings in the existing technology and has high industrial utilization value.

The above-mentioned embodiments are just used for exemplarily describing the principle and effects of the present disclosure instead of limiting the present disclosure. Those skilled in the art can make modifications or changes to the above-mentioned embodiments without going against the spirit and the range of the present disclosure. Therefore, all equivalent modifications or changes made by those who have common knowledge in the art without departing from the spirit and technical concept disclosed by the present disclosure shall be still covered by the claims of the present disclosure.

1. A method for preparing heterostructure, comprising:
1) providing a donor substrate and forming a sacrificial layer on a surface of the donor substrate;
2) forming a thin film cover layer on a surface of the sacrificial layer, wherein a top surface of the thin film cover layer is an implantation surface;
3) performing ion implantation from the implantation surface, such that a defect layer is formed in the sacrificial layer;
4) providing an acceptor substrate, and bonding the acceptor substrate to the implantation surface of the thin film cover layer;
5) removing the sacrificial layer along the defect layer, so as to separate the acceptor substrate bonded with the thin film cover layer from the donor substrate, to obtain a heterostructure of acceptor substrate-thin film cover layer.

2. The method for preparing heterostructure according to claim 1, wherein step 1) further comprises forming a buffer layer on the surface of the donor substrate, and the buffer layer is formed between the donor substrate and the sacrificial layer.

3. The method for preparing heterostructure according to claim 1, wherein in step 1), a material of the sacrificial layer is an aluminum-containing compound.

4. The method for preparing heterostructure according to claim 3, wherein the aluminum-containing compound is any one of a group consisting of AlP, AlAs, AlSb, and Al (GaIn) (PAsSb).

5. The method for preparing heterostructure according to claim 3, further comprising step 6), surface-treating the sacrificial layer obtained after stripping by autoxidation, such that the sacrificial layer is easy to clean.

6. The method for preparing heterostructure according to claim 1, wherein a thickness of the thin film cover layer ranges from 20 to 1000 nm.

7. The method for preparing heterostructure according to claim 1, wherein in step 1), the donor substrate is any one of a group consisting of a Si substrate, a Ge substrate, a GaP substrate, a GaAs substrate, an InP substrate, a GaSb substrate, an InAs substrate, an InSb substrate, a group II-VI substrate, and a group IV-VI substrate.

8. The method for preparing heterostructure according to claim 1, wherein in step 3), the defect layer is spaced from a top surface of the sacrificial layer, and is spaced from a bottom surface of the sacrificial layer.

9. The method for preparing heterostructure according to claim 1, wherein in step 3), the ion implantation is any one of a group consisting of hydrogen ion implantation, helium ion implantation, and hydrogen-helium ion co-implantation.

10. The method for preparing heterostructure according to claim 9, wherein an energy of the ion implantation is 10 to 200 keV, a dose of the ion implantation is 1×10¹⁶ to 3×10¹⁷ cm⁻², and a temperature of the ion implantation is −50 to 300° C.

11. The method for preparing heterostructure according to claim 1, wherein in step 4), a bonding temperature ranges from room temperature to 500° C.

12. The method for preparing heterostructure according to claim 1, wherein in step 4), the acceptor substrate is any one of a group consisting of a silicon substrate, a silicon on insulator substrate, and a silicon carbide substrate.

13. The method for preparing heterostructure according to claim 1, wherein in step 5), a structure obtained in step 4) is annealed to remove the sacrificial layer along the defect layer, and an annealing temperature is 50 to 500° C.

14. The method for preparing heterostructure according to claim 4, further comprising step 6), surface-treating the sacrificial layer obtained after stripping by autoxidation, such that the sacrificial layer is easy to clean.
